(19) United States
(12) Patent Application Publication
(10) Pub. No.: US 2014/0352758 A1
(43) Pub. Date: Dec. 4, 2014

(54) SOLAR CELL MODULE

(71) Applicant: Electronics and Telecommunications Research Institute, Daejeon (KR)

(72) Inventor: Seok-Hwan MOON, Daejeon (KR)

(73) Assignee: Electronics and Telecommunications Research Institute, Daejeon (KR)

(21) Appl. No.: 14/177,890

(22) Filed: Feb. 11, 2014

(30) Foreign Application Priority Data
May 29, 2013 (KR) 10-2013-0061178

(51) Int. Cl. H01L 31/052; H01L 31/042

(52) U.S. Cl. CPC H01L 31/052; H02S 40/00
USPC 136/246

(57) ABSTRACT

Provided is a solar cell module. The solar cell module includes a heat sink, a light guide plate on the heat sink, a cooling part passing through a center of the light guide plate between the light guiding plate and the heat sink, the cooling part extending from a center of the heat sink up to each of edges of the heat sink, solar cells fixed to the cooling part, and a light concentrating plate disposed on the solar cells, cooling part, and the light guiding plate to concentrate solar light onto the light guide plate and the solar cells.

### CROSS-REFERENCE TO RELATED APPLICATIONS

This U.S. non-provisional patent application claims priority under 35 U.S.C. §119 of Korean Patent Application No. 10-2013-0061178, filed on May 29, 2013, the entire contents of which are hereby incorporated by reference.

### BACKGROUND OF THE INVENTION

The present invention disclosed herein relates to a solar cell module, and more particularly, to a solar cell module having excellent heat dissipation performance.

Typically, solar cells for photoelectric conversion are fabricated by using silicon that is a semiconductor. However, in recent years, various materials such as monocrystalline, polycrystalline, and amorphous are being used to fabricate solar cells. The solar cells operate on the principle in which current is generated according to electron transfer due to incident solar energy to generate electricity.

A solar cell module that is an assembly of solar cells may be a light-gathering medium into which sunlight is directly incident for a long time. Particularly, under the burning sun in the middle of summer, the solar cell module may generate a high temperature of about 60° C. to about 70° C. or more. Here, solar cells may be significantly reduced in efficiency due to the high temperature and also may be broken down or burst and malfunction. Thus, adequate solutions for the above-described limitations are needed when considering domestic weather conditions such as the appreciable changing seasons, i.e., a large temperature difference of about 30° C. to about 40° C. between the summer season and the winter season.

Solar cells may operate within only a range of a predetermined temperature to generate electricity. If the solar cells are overheated at the predetermined temperature or more, the solar cells may be deteriorated in function, a control circuit may be stopped in operation. Thus, a heat dissipation unit for the solar cells from being overheated to maintain the solar cells at a predetermined temperature may be provided in a solar cell module.

In particular, in case of a concentrating solar cell module, since a large amount of heat is generated in a back surface of the solar cell module, the solar cell module may normally operate through only a high heat flux per unit area. In this case, the solar cell module has to be designed in consideration of a high-performance cooling solution without providing only a heat sink.

FIG. 1 illustrates a typical concentrating solar cell module.

Referring to FIG. 1, a typical concentrating solar cell module includes a housing 10, first and second concentrating lenses 12 and 15, a solar cell 20, a chip 22, and a heat sink frame 24. The housing 10 may accommodate the solar cell 20 and may fix the first and second concentrating lenses 12 and 14. The first concentrating lens 12 may be fixed to an upper end of the housing 10. The second concentrating lens 14 may be disposed on the solar cell 20 disposed on a bottom inside the housing 10. The solar cell 20 may be mounted on the chip 22. The heat sink frame 24 may reduce a heating temperature of the solar cell 20 and the chip 22.

The typical concentrating solar cell module has a disadvantage in that, as a predetermined focusing distance is required, the whole size, i.e., a thickness of a housing is relatively large. Thus, since sunlight concentrated by a lens is transferred to several solar cells on a very narrow area to increase a heat generation rate per unit area, an effective dissipation unit is needed in design and application.

### SUMMARY OF THE INVENTION

The present invention provides a solar cell module which is capable of minimizing thermal loss of solar energy.

The present invention also provides a solar cell module which is capable of maximizing reliability and lifetime of the solar cell.

Embodiments of the inventive concepts provide solar cell modules including: a heat sink; a light guide plate on the heat sink; a cooling part passing through a center of the light guide plate between the light guiding plate and the heat sink, the cooling part extending from a center of the heat sink up to each of edges of the heat sink; solar cells fixed to the cooling part; and a light concentrating plate disposed on the solar cells, cooling part, and the light guiding plate to concentrate solar light onto the light guide plate and the solar cells.

In some embodiments, the cooling part may include: cooling pillars disposed on the center of the heat sink, the cooling pillars fixing the solar cells; and heat pipes connected to the cooling pillars, the heat pipes extending from the center of the heat sink to the edges of the heat sink, respectively.

In other embodiments, each of the heat pipes may include: an evaporation section inserted into the cooling pillars; and a condensation section connected to the evaporation section, the condensation section disposed between the light guiding plate and the heat sink.

In still other embodiments, the heat sink may have a square shape, wherein the condensation section of each of the heat pipes may extend in a diagonal direction of the square shape.

In even other embodiments, each of the cooling pillars of the cooling part may have a hexahedral shape.

In yet other embodiments, a square cross-section of the hexahedral shape and the square shape may be aligned in the same direction to one-to-one correspond to each other.

In further embodiments, the square cross-section of the hexahedral shape of each of the cooling pillars and the square shape may be twisted at about 45 degrees with respect to each other.

In still further embodiments, each of the heat pipes may have a capillary wick structure through which a refrigerant flows.

In even further embodiments, each of the cooling pillars may have a hole in which the heat pipe is inserted.

In yet further embodiments, the cooling pillars and the heat pipes may have the same cross-section.

In much further embodiments, each of the cooling pillars and the heat pipes may have a rectangular, semicircular, or T-shaped cross-section.

In still much further embodiments, the light guide plate may have reflecting inclined planes having a first concentric circle that is inclined in a direction of the solar cells.

In even much further embodiments, the light concentrating plate may have transmitting refraction surfaces having a second concentric circle.

In yet much further embodiments, each of the light concentrating plate and the light guiding plate may include poly methyl methacrylate or polymer.

In yet much further embodiments, the solar cell modules may further include a slab disposed on each of edges of the light concentrating plate and the light guiding plate, the slab separating the light concentrating and the light guiding plate.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view illustrating a typical concentrating solar cell module;

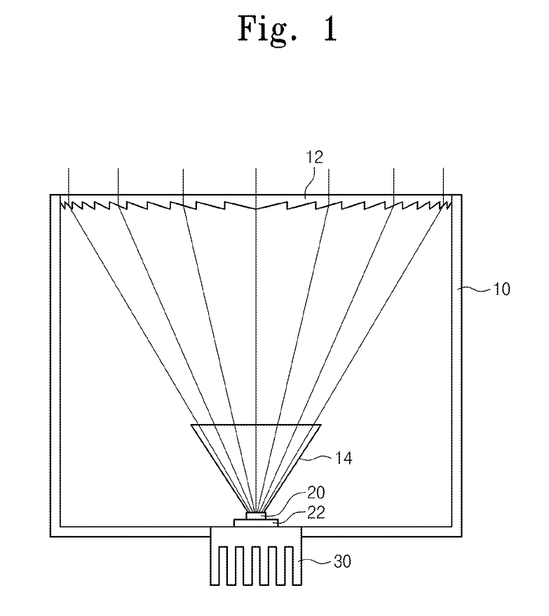

FIG. 2 is a perspective cross-sectional view of a solar cell module according to an embodiment of the inventive concepts;

FIG. 3 is an exploded perspective view of the solar cell module according to an exemplary embodiment of the inventive concepts;

FIG. 4 is a perspective view illustrating a coupled configuration of the solar cell module of FIG. 3;

FIG. 5 is a perspective view illustrating cooling pillars and solar cells of FIGS. 3 and 4;

FIGS. 6A to 6C are perspective views of heat pipes of FIG. 3;

FIG. 7 is a perspective view of a cooling part and a solar cell on a heat sink; and

FIG. 8 is a perspective view illustrating an arrangement relationship between the cooling pillars of the cooling part and the heat pipes.

### DETAILED DESCRIPTION OF PREFERRED EMBODIMENTS

Advantages and features of the present invention, and implementation methods thereof will be clarified through following embodiments described with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explain a specific exemplary embodiment while not limiting the present invention. The terms of a singular form may include plural forms unless referred to the contrary. The meaning of “include,” “comprise,” “including,” or “comprising,” specifies a component, a process, and/or an element but does not exclude other components, processes, and/or elements.

Additionally, the embodiment in the detailed description will be described with sectional and/or plan views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

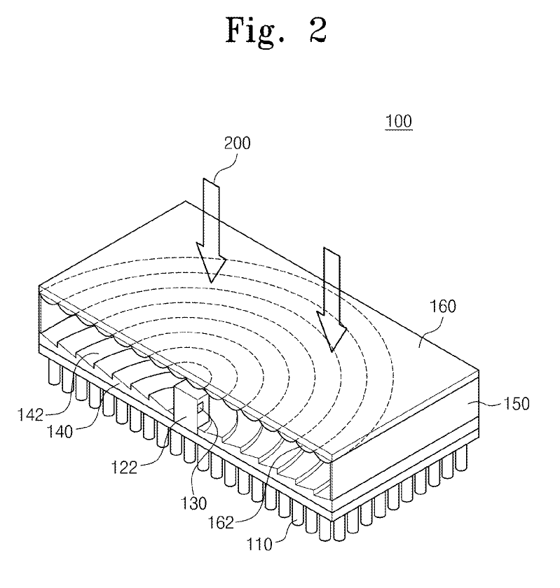

FIG. 2 illustrates a solar cell module according to an embodiment of the inventive concepts. A solar cell module according to an embodiment of the inventive concepts may include a heat sink 110, cooling pillars 122, a solar cell 130, a light guide plate 140, a slab 150, and a light concentrating plate 160.

The heat sink 110 may dissipate heat from the solar cell 130, the light guide plate 140, and the light concentrating plate 160. The light guide plate 140 and cooling pillars 122 are disposed on the heat sink 122. The heat sink 100 may be a radiating plate of which a bottom surface has a maximized in surface area. The heat sink 110 may have a square shape.

The cooling pillars 122 are disposed on a center of the heat sink 110. The cooling pillars 122 may have a hexahedral shape. The solar cells 130 are fixed to each of four surfaces of the cooling pillars 122, respectively. Each of the bottom surfaces of the cooling pillars 122 may be supported by the heat sink 110, and each of top surfaces of the cooling pillars 122 may contact the light concentrating plate 160. Also, the cooling pillars 122 may pass through a center of the light guide plate 140. The solar cells 130 may convert solar energy into electrical energy. For example, the solar cell 130 may include a silicon solar cell, a quantum dot solar cell, a copper indium gallium diselenide (CIGS) cell, or a dye-sensitized solar cell.

The light guide plate 140 may cover the heat sink 110. The slab 150 may be disposed between the light guide plate 140 and the light concentrating plate 160. A distance between the guide plate 140 and the light concentrating plate 160 may be defined by heights of the slab 150 and the cooling pillar 122. The slab 150 may be disposed on each of edges of the light concentrating plate and the light guiding plate. A space between the light concentrating plate 160 and the light guide plate 140 may be filled with air mainly. Solar light may be concentrated by the light concentrating plate 160 and the light guide plate 140 and then may be incident into the solar cell 130. The light guide plate 140 may have reflecting inclined surfaces 142 having a first concentric circle. The reflecting inclined surfaces 142 may be disposed on a top surface of the light guide plate 140. The light guide plate 140 and the light concentrating plate 160 may include poly methyl methacrylate (PMMA) or polymer.

The light concentrating plate 160 may allow solar light to be concentrated onto the light guide plate 130. The light concentrating plate 160 may have transmitting refraction surfaces 162 having a second concentric circle. Each of the transmitting refraction surfaces 162 may have an annual ring-shaped boundary, but the present invention is not limited thereto. For example, the light concentrating plate 160 may have a refractive index gradually increasing in a central direction.

The solar cell 130 may be heated by solar light. The solar cell 130 may be formed of the III-V group compound semiconductor. The semiconductor may increase in resistance up to about 150° C. at room temperature. The solar cell 130 may decrease in photoelectric conversion efficiency at high temperature. The cooling pillar 122 and the heat sink 110 may keep the solar cell 130 at room temperature. Thus, the solar cell 130 may increase in reliability and lifetime.

Therefore, the solar cell module according to an embodiment of the inventive concepts may enable the solar cell 130 to be maximized in reliability and lifetime.

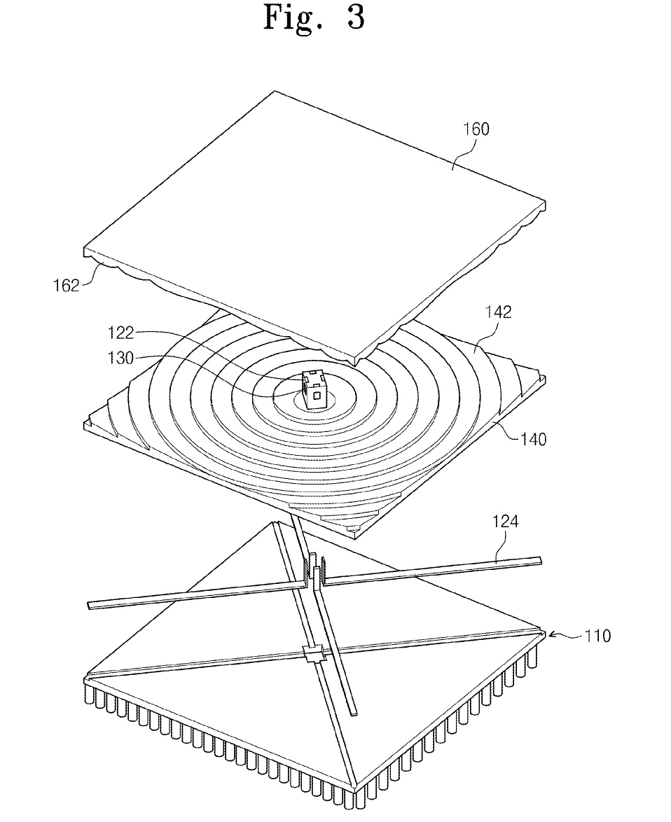

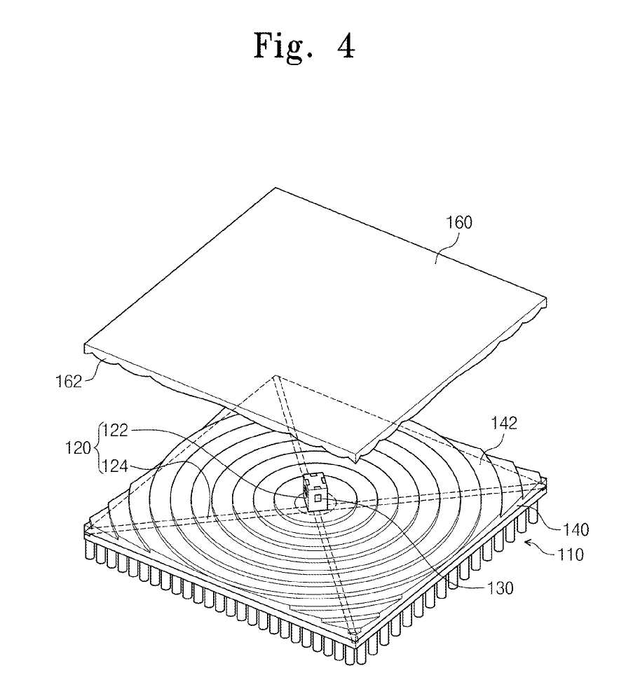

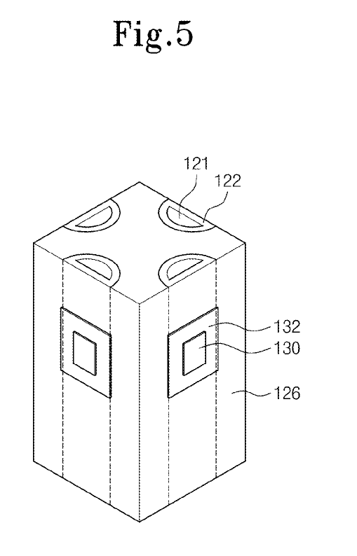

FIG. 3 is an exploded perspective view of the solar cell module according to an exemplary embodiment of the inventive concepts, FIG. 4 is a perspective view illustrating a coupled configuration of the solar cell module of FIG. 3, and FIG. 5 is a perspective view illustrating cooling pillars and solar cells of FIGS. 3 and 4.

Referring to FIGS. 3 to 5, the solar cell module according to an exemplary embodiment of the inventive concepts may include heat pipes 124 respectively connected to the cooling pillars 122. The cooling pillars 122 and the heat pipes 124 may constitute cooling parts 120, respectively. The cooling parts 120 may transfer heat of the solar cell 130 to the heat sink 110. The heat pipes 124 may be connected to the cooling pillars 122, respectively. The cooling pillars 122 may adhere to each other by using an adhesive 126 to form a hexahedral shape, but the present invention is not be limited thereto. For example, the cooling pillars 122 may be gathered to form a cylindrical shape. Each of the cooling pillars 122 may have a side surface wider than that of the solar cell 130. The solar cells 130 may be fixed to the cooling pillars 122 by a panel 132, respectively.

The heat pipes 124 may transfer heat between the cooling pillar 122 and the heat sink 110. More particularly, a portion of the heat pipe 124 may be inserted into the cooling pillar 122. The heat pipe 124 may transfer heat within the cooling pillar 122 to the heat sink 110. The cooling pillar 122 may have a hole 121 for accommodating the heat pipe 124. The heat pipes 124 may be coupled to the heat sink 110 having a square shape in a diagonal direction. The coupling in the diagonal direction may maximize surface-contact between the heat pipes 124 and the heat sink 110. The cooling pillar 122 having the hexahedral shape may be disposed at about 45 degrees with respect to the heat sink 110 having the square shape. That is, a square cross-section of the cooling pillar 122 having the hexahedral shape and the square shape of the heat sink 110 may be twisted at about 45 degrees with respect to each other. This is because a flat surface of the cooling pillar 122 may be disposed in the same direction as that in which the heat pipe 124 is disposed. Therefore, it may prevent the cooling pillar 122 and heat pipe 124 from being twisted or deformed in cross-sectional structure.

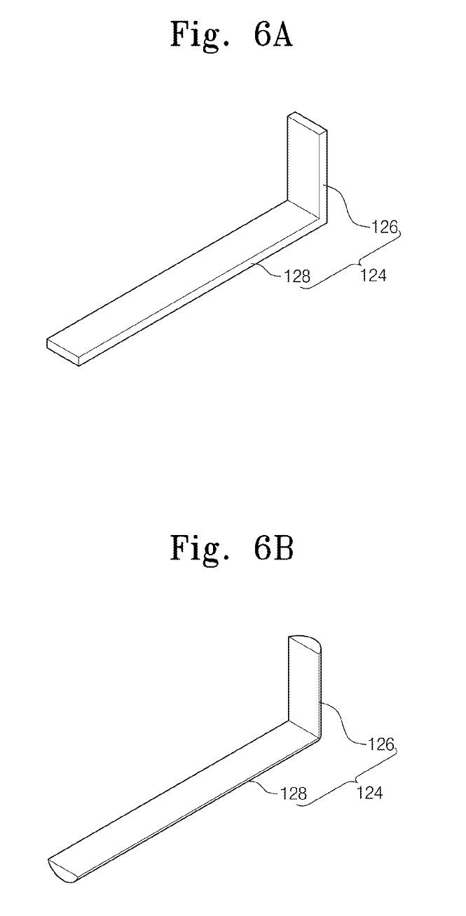

FIGS. 6A to 6C are perspective views of heat pipes of FIG. 3.

Referring to FIGS. 6A to 6C, each of the heat pipes 124 may include an evaporation section 126 and a condensation section 128. The evaporation section 126 is an area inserted into the cooling pillar 122. The evaporation section 126 of the heat pipe 124 may have a cross-section less than that of the cooling pillar 122. The condensation section 128 is an area adhering to the heat sink 110.

The heat pipe 124 may be in a vacuum state and may transfer heat from the cooling pillar 122 to the heat sink 110 by using a gas-liquid phase change heat transfer mechanism. The heat pipe 124 may have a capillary wick structure. The capillary wick structure may significantly increase thermal transfer performance regardless of a change in position of the solar cell module 100. For example, when the concentrating module is inclined according to an incident angle of solar light, the evaporation section 126 of the heat pipe 124 may be disposed under the condensation section 128. Since a refrigerant has to be transferred in a direction opposite to the gravity in the heat pipe 124, the capillary performance of the heat pipe 124 may be a very important working factor. For example, the heat pipe 124 may have a rectangular (see FIG. 6A), semicircular (see FIG. 6B), or T-shaped cross-section.

The heat pipe 124 having the rectangular cross-section illustrated in FIG. 6A may have a flat plate shape and be easily couple to the cooling pillar 122 and the heat sink 110.

The heat pipe 124 having the semicircle cross-section illustrated in FIG. 6B may have an advantage in flow of steam inside thereof, i.e., excellent heat transfer efficiency. Also, the heat pipe 124 having the semicircular cross-section may be easily inserted into the cooling pillar 122. It is advantageous in aspect of packaging when the plane of the heat pipe 124 having the semicircular or half-moon-shaped cross-section is disposed in the cooling pillar to face the outside.

The heat pipe 124 having the T-shaped cross-section illustrated in FIG. 6C may be easy to fabricate the capillary wick on an edge thereof. The edge of the T-shaped cross-section may correspond to a vertex of a triangle. Also, The T-shaped cross-section may be a triangular cross-section.

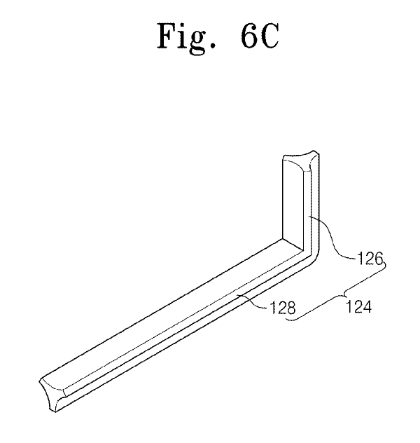

FIG. 7 is a perspective view of a cooling part and a solar cell on a heat sink.

Referring to FIG. 7, at least two heat pipes 124 of the cooling part 120 may be coupled to one cooling pillar 122. As described above, the evaporation section 126 of each of the heat pipes 124 may be inserted to the cooling pillar 122. Thus, the solar cells 130 may be cooled by the evaporation sections 126 of the plurality of the heat pipes 124.

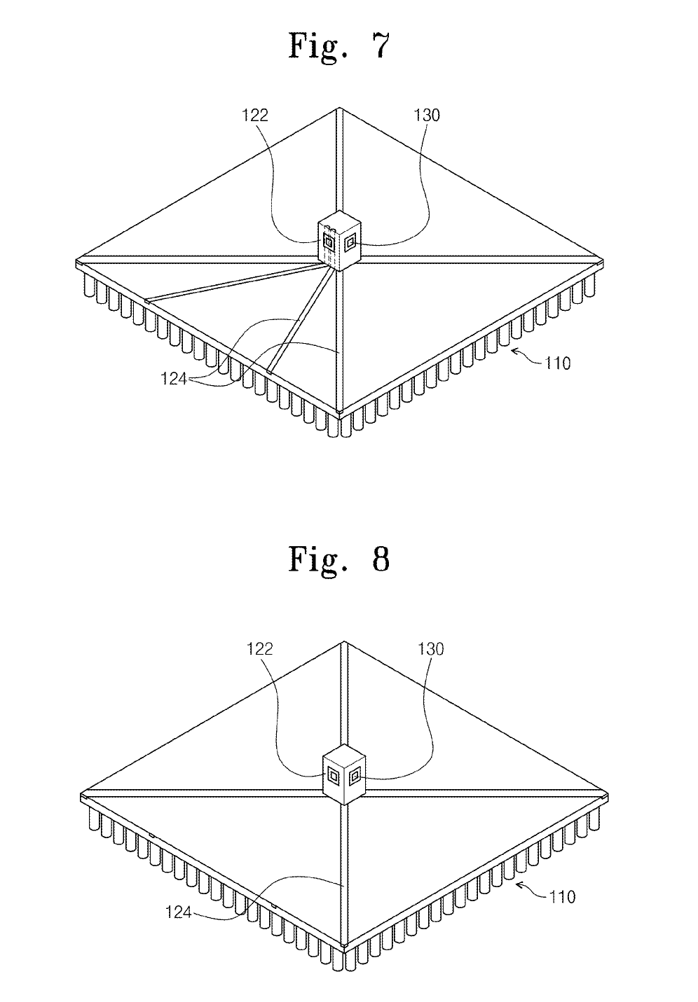

FIG. 8 is a perspective view illustrating an arrangement relationship between the cooling pillars of the cooling part and the heat pipes.

Referring to the FIG. 8, the square cross-section of the cooling pillar 122 having the hexahedral shape may be aligned in the same direction as the square shape of the heat sink 110. The cooling pillars 122 and the solar cells 130 may one-to-one correspond to four sides of the square shape of the heat sink 110, respectively.

The solar cell module according to the embodiment of the inventive concepts may include the heat sink, the cooling parts, the solar cell, the light guide plate, and the light concentrating plate. The cooling parts may fix the solar cell to the heat sink and cool the solar cell. The light guide plate may be disposed on the heat sink. The light concentrating plate may be disposed on the light guide plate, the cooling part, and the solar cell. The cooling part may include the cooling pillars disposed on the center of the heat sink and the heat pipes respectively connected to the cooling pillars to extend along the plane of the heat sink. The cooling pillar may pass through the light guide plate and be fixed to the heat sink. The heat pipe may cool the cooling pillar and the solar cells fixed to the cooling pillar. When the solar cell is heated at a high temperature, efficiency thereof may be reduced. Thus, the heat pipe may keep the solar cell at room temperature to improve efficiency in the solar cells.

Therefore, the solar cell module according to the embodiment of the inventive concepts may be maximized in reliability and lifetime.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A solar cell module comprising:
a heat sink;
a light guide plate on the heat sink;
a cooling part passing through a center of the light guide plate between the light guiding plate and the heat sink, the cooling part extending from a center of the heat sink up to each of edges of the heat sink;
solar cells fixed to the cooling part; and
a light concentrating plate disposed on the solar cells, cooling part, and the light guiding plate to concentrate solar light onto the light guide plate and the solar cells.

2. The solar cell module of claim 1, wherein the cooling part comprises:
cooling pillars disposed on the center of the heat sink, the cooling pillars fixing the solar cells; and
heat pipes connected to the cooling pillars, the heat pipes extending from the center of the heat sink to the edges of the heat sink, respectively.

3. The solar cell module of claim 2, wherein each of the heat pipes comprises:
an evaporation section inserted into the cooling pillars; and
a condensation section connected to the evaporation section, the condensation section disposed between the light guiding plate and the heat sink.

4. The solar cell module of claim 3, wherein the heat sink has a square shape,
wherein the condensation section of each of the heat pipes extends in a diagonal direction of the square shape.

5. The solar cell module of claim 4, wherein each of the cooling pillars of the cooling part has a hexahedral shape.

6. The solar cell module of claim 5, wherein a square cross-section of the hexahedral shape and the square shape are aligned in the same direction to one-to-one correspond to each other.

7. The solar cell module of claim 5, wherein the square cross-section of the hexahedral shape of each of the cooling pillars and the square shape are twisted at about 45 degrees with respect to each other.

8. The solar cell module of claim 2, wherein each of the heat pipes has a capillary wick structure through which a refrigerant flows.

9. The solar cell module of claim 2, wherein each of the cooling pillars has a hole in which the heat pipe is inserted.

10. The solar cell module of claim 2, wherein the cooling pillars and the heat pipes have the same cross-section.

11. The solar cell module of claim 10, wherein each of the cooling pillars and the heat pipes has a rectangular, semicircular, or T-shaped cross-section.

12. The solar cell module of claim 11, wherein the light guide plate has reflecting inclined planes having a first concentric circle that is inclined in a direction of the solar cells.

13. The solar cell module of claim 1, wherein the light concentrating plate has transmitting refraction surfaces having a second concentric circle.

14. The solar cell module of claim 1, wherein each of the light concentrating plate and the light guiding plate comprise poly methyl methacrylate or polymer.

15. The solar cell module of claim 1, further comprising a slab disposed on each of edges of the light concentrating plate and the light guiding plate, the slab separating the light concentrating plate and the light guiding plate.
